(19) United States
(12) Patent Application Publication
(10) Pub. No.: US 2013/0170136 A1
(43) Pub. Date: Jul. 4, 2013

(54) PCB HEAT SINK FOR POWER ELECTRONICS

(71) Applicant: Joshua L. Roby, Battle Creek, MI (US)

(72) Inventor: Joshua L. Roby, Battle Creek, MI (US)

(21) Appl. No.: 13/341,994

(22) Filed: Dec. 31, 2011

(51) Int. Cl. H05K 7/20

(52) U.S. Cl. 361/692; 174/252; 361/707; 361/709

(57) ABSTRACT

A PCB with improved cooling. Openings are provided below electronic components on the PCB of an electronics device. Raised mounts or bosses on the device housing or base extend into the openings and make contact with the electronic components to act as heat sinks. A thermal pad member can be positioned between the bosses and the components to aid in the contact and heat conduction. Other embodiments include direct contact of the raised mounts or bosses with the PCB and through openings are not provided.

### TECHNICAL FIELD

Systems and methods for cooling PCBs are disclosed, particularly utilizing heat sinks.

### BACKGROUND

Printed Circuit Boards (PCBs) are well known. They are utilized in most electrical devices in use today. PCBs are used to mechanically support and electronically connect electronic components using pathways, tracks, signal traces, etc. etched from metal sheets (preferably copper) laminated onto a nonconductive substrate (or backing member).

PCBs typically contain a plurality of electronic devices, such as transistors and resistors, which are physically attached to the substrate. The metal circuitry printed (etched on the PCBs provides the necessary electrical connections between the components and provides electrical energy power for them to operate.

One of the primary challenges in the design of power electronics is effectively removing the heat that is generated in silicon devices such as power diodes and Field Effect Transistors (FETs). Although there are heat sinks commercially available for power electronic devices, they typically rely on convective transfer of heat to the surrounding air, which is fundamentally limited by convective heat transfer rates. This problem is especially a challenge with surface mount technology because the metal components of the silicon device are attached to the PCBs.

Another principal problem and limitation with PCBs is thermal degradation. The electronic devices dispense thermal energy when they are electronically performing ₜheir intended functions. There have been many systems and methods used to attempt to dissipate or remove the heat generated by the components on PCBs. These systems typically include cooling fans for larger electronic devices and cooling fins or similar structures for smaller electronic devices which spread out the heat and allow it to dissipate into the atmosphere.

One of the objects of the present invention is to provide improved methods and systems for removing and dissipating heat generated by the electronic components on PCBs.

### SUMMARY OF THE INVENTION

In accordance with embodiments of the present invention, heat sinks are provided for one or more of the electronic components on a PCB or in another electronic system that needs additional cooling. Openings, preferably through-openings, are provided on the PCB substrates (or backing members) underneath or below specified electronic components. Raised bosses or mounts are positioned in or on the housing or base member for the PCBs which correspond to and mate with the openings. These raised bosses and mounts are then utilized as heat sinks.

The top or upper surfaces of the bosses or mounts are positioned in contact with the electronic components through the openings in the PCBs. In this manner, the heat generated by the electronic components is conducted from the silicon die through the component's internal heat sink plate and into the housing or base member boss. From the housing or base member, the heat is then convectively transferred to the atmosphere.

In one embodiment, a thermal gap pad is positioned between the electronic components and the raised bosses or mounts. The pad is preferably soft or moldable in order to provide a large and tight surface-to-surface contact between the electronic components and the bosses or mounts in order to conduct away as much heat as possible from the electronic components. The gap pad material accommodates the tolerance stackup variation between the assembly of the housing, PCB, and surface mount electronic components. It also helps improve heat transfer from the electronic component to the housing by filling the voids created between the two surfaces by surface asperities.

Other objects, features, benefits and advantages of the present application will become apparent from the following description of preferred embodiments of the invention when viewed in accordance with the accompanying drawings and appended claims.

### BRIEF DESCRIPTION OF THE DRAWINGS

FIG. 1 is a perspective view of a representative PCB.

FIG. 2 is a perspective view of representative heat generating electronic devices typically used with PCBs.

FIG. 3 is a cross-sectional view of a PCB utilizing an embodiment of the present invention.

FIG. 4 is a cross-sectional view of a PCB utilizing another embodiment of the present invention.

### DESCRIPTION OF THE PREFERRED EMBODIMENTS

For the purpose of promoting and understanding the principles of the present invention, reference will now be made to the embodiments illustrated in the drawings and specific language will be used to describe them. It will nevertheless be understood that no limitation as to the scope of the invention is hereby intended. The invention includes any alternatives and other modifications in the illustrated devices and described methods and further applications of the principles of the invention which would normally occur to persons or ordinary skill in the art to which the invention relates.

The present invention relates to systems and methods for improving the cooling of high power electronic components on printed circuit boards (PCBs) in electronic devices or the like. The electronic components utilized on PCBs can generate a significant amount of thermal energy or heat. This heat can be degrading or limiting to one or more of the electronic components, and it is important to maintain the PCB and components at cool temperatures in order to optimize performance and minimize premature failures.

The invention provides for significantly improving the heat transfer from surface mounted power electronics to a heat sink. This enables devices to be operated at much higher current levels without exceeding their maximum junction temperature. It also means that in many designs lower cost devices which have higher internal resistance can be used in place of more costly components.

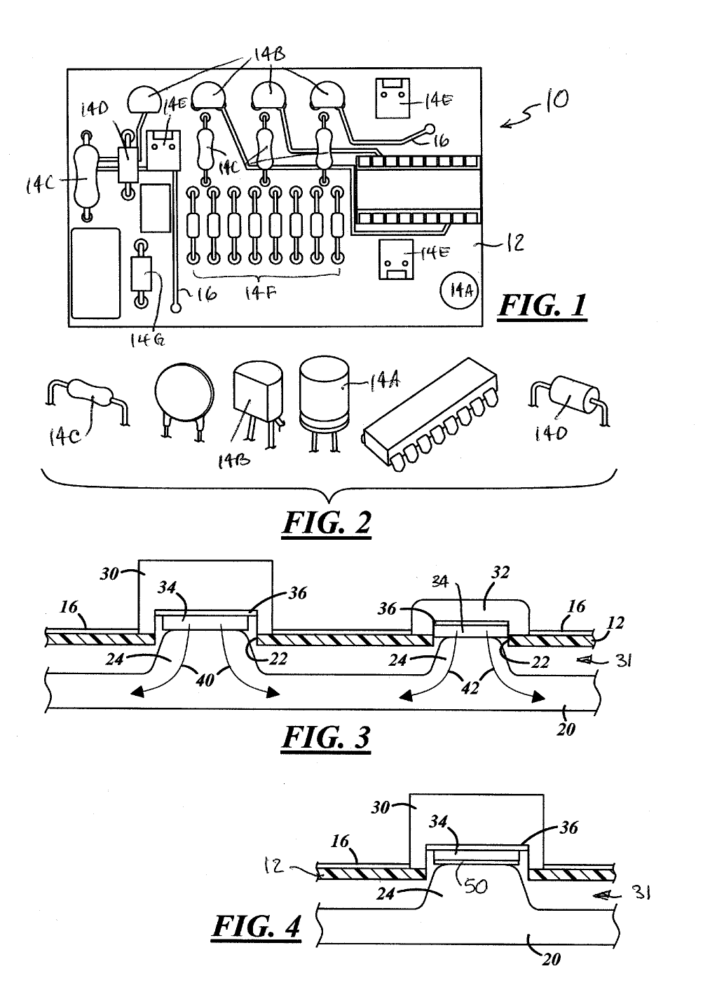

A representative printed circuit board (PCB) 10 is depicted in FIG. 1. The present invention can be utilized with a PCB similar to the one depicted or virtually any other PCB used in any electronic device. As shown in FIG. 1, the PCB 10 has a substrate or backing member 12 and a plurality of electronic components 14A-14G positioned and secured on its surface. In addition, a plurality of electronic pathways or traces 16 are positioned on the PCB and extend between and connect the electronic components in a prespecified manner and sequence.

The substrate or backing member 12 for the PCB is made from a non-conducting material and preferably is non-flexible. Also, the PCB 10 is typically mounted in or on a housing or base member 20 (shown in FIGS. 3 and 4). An air space 31 is typically provided between the PCB and the housing.

The electronic pathways or tracks 16 are typically made of a conductive metal material, such as copper. A piece of copper film material is laminated to the PCB substrate and the desired pattern of pathways or traces is typically produced by etching. The pathways or traces connect together the various electronic components on the PCB in a particular sequence or pattern as desired for operation of the electronic device. The pathways or traces also connect the PCB electronically to a power source such as a battery or AC Voltage source.

Representative electronic components which can be used on a typical PCB are shown in FIG. 2. These electronic components can be, for example, transistors, resistors, potentiometers, capacitors, inductors, crystals/oscillators, relays, transformers, fuses, diodes, microcontrollers, and other integrated circuits. Batteries also could be provided on the PCB. Most or virtually all of these electronic components generate thermal energy during use which results in heat being produced by the PCB. The electronic components are typically surface mounted on one side of the PCB, although some components, pathways and tracks could be provided on both sides of the PCB.

The housing or base member 20 for the electronic device and which holds, mounts or supports the PCB internally in the device, is typically made from a plastic or metal material. For purposes of the present invention, it is preferable that the housing 20 on which the PCB is mounted is a highly conductive metal material, such as aluminum. Other materials could also be used, although the ability of the housing 20 to act as a good heat sink is preferred.

As shown in FIG. 3, one or more openings 22 are provided in the PCB substrate 12 in this embodiment. The openings 22 are preferably through-openings, i.e. openings that pass entirely through the PCB substrate. It is possible, however, to also have the openings formed substantially through the substrate, or for a piece of conducting material to be positioned in the near-through-openings to aid in the conduction of heat from the electronics compartment to the housing member. With through-openings, the mounts or bosses on the housings can pass completely through the PCB in order to mate with the components.

In accordance with the invention, one or more raised mounts or bosses 24 are provided or formed on the housing or conductive base member 20. The mounts or bosses are positioned to align with the openings 22 as indicated in this embodiment. In addition, the electronic components 30 and 32 are mounted on the PCB over the openings 22—again as illustrated in FIG. 3.

Although it is possible to have the upper surfaces of the raised mountings or bosses make contact directly with the electronic components, preferably thermal heat sink tab members 34 are provided on the electronic components to aid in making the contact and being a heat conductor. The thermal heat sink tab members 34 can be secured to the electronic component by silicon or another adhesive 36.

The heat flow for the conduction of heat from the electronic components to and into the heat sink housing or base member 20 is shown by arrows 40 and 42.

The number of raised mounts and openings depends on the design of the PCB and electronic device and the amount of heat desired to be dissipated from the electronic components. Thus, in accordance with the present invention, there could be only one opening and mount with respect to one component in one system, or there could be a plurality of openings and raised mounts corresponding to a plurality of electronic components in another system. The precise member is not critical to the invention.

Another embodiment of the invention is shown in FIG. 4. The elements of this embodiment which are the same as those shown in FIG. 3 are identified by the same reference numbers. The principal difference is the addition of a thermal gap pad 50 which is positioned between the electronic component 30 (with or without the thermal heat sink tab 34) and the upper surface of the raised mount or boss 24.

The thermal gap pad 50 accounts for the mechanical tolerance stackup. It is made of a softer, formable thermally conductive material and improves the heat transfer between the raised heat sink boss and the component (or heat sink tab) by filling any imperfections or micro surface asperities with thermally conductive material. Although these thermal gap pad materials have high thermal conductivity they are typically electrical insulators.

In another preferred embodiment, the electronic devices are surface mounted on one upper surface of the PCB and the heat sink bosses with heat sink tabs are positioned in contact with the lower surface of the PCB. In this embodiment,. through-holes are not provided in the PCB under the electronic devices.

As indicated, the invention provides for significantly improving the heat transfer from surface mounted power electronics to a heat sink. This enables devices to be operated at much higher current levels without exceeding their maximum junction temperature. It also means that in many designs, lower cost devices which have higher internal resistance can be used in place of more costly components.

Although the invention has been described with respect to preferred embodiments, it is to be also understood that it is not to be so limited since changes and modifications can be made therein which are within the full scope of this invention as detailed by the following claims.

What is claimed is:

1. A power electronics cooling system comprising:
a base member;
a PCB positioned adjacent to said base member;
said PCB having at least one opening;
an electronic component positioned on the PCB over said opening;
a raised boss on said base member positioned to mate with said opening and having a height to make contact with the electronic component.

2. The cooling system as described in claim 1 wherein:
a plurality of openings are provided in the PCB;
at least two electronic components are provided, each of said two electronic components being positioned over one of said plurality of openings;
at least two raised bosses one provided in said base member;
said two raised bosses being positioned to mate with said openings under said two electronic components and having a height to make contact with said electronic components.

3. The cooling system as described in claim 1 further comprising a thermally conductive pad member positioned on said raised boss and between said boss and said electronic components.

4. The cooling system as described in claim 2 further comprising at least two conductive pad members are provided, each of said conductive pad member positioned on one of said bosses and between said boss and one of said electronic components.

5. The cooling system as described in claim 3 wherein said conductive pad members are thermal gap pad members.

6. The cooling system as described in claim 4 wherein said conductive pad members are thermal gap pad members.

7. The cooling system as described in claim 1 wherein said openings in said PCB are through-openings.

8. The cooling system as described in claim 1 wherein said boss member is made of aluminum or another heat conducting material.

9. The cooling system as described in claim 2 wherein each of said openings in said PCB are through-openings.

10. A power electronics cooling system comprising a base member, a PCB positioned on said base member, at least one electronic device positioned on the upper surface of the PCB, a raised boss member on said base member and being in contact with the lower surface of the PCB directly beneath said one electronic device.

11. The power electronics cooling system as described in claim 10 wherein a plurality of electronic devices and corresponding raised bosses are provided.

12. The power electronics cooling system as described in claim 10 further comprising a heat sink tab positioned on said raised boss.

13. The power electronics cooling system as described in claim 11 wherein heat sink tabs are positioned on all of said raised bosses.
